(19) United States
(12) Patent Application Publication
(10) Pub. No.: US 2012/0248568 A1
(43) Pub. Date: Oct. 4, 2012

(54) METHOD FOR CONTROLLING THE ELECTRICAL CONDUCTION BETWEEN TWO METALLIC PORTIONS AND ASSOCIATED DEVICE

(75) Inventor: Serge Blonkowski, Meylan (FR)

(73) Assignee: STMicroelectronics (Crolles 2) SAS, Crolles (FR)

(21) Appl. No.: 13/435,304

(22) Filed: Mar. 30, 2012

(30) Foreign Application Priority Data
Apr. 1, 2011 (FR) 1152825

(51) Int. Cl. H01L 21/326; H01L 23/525; H01L 21/768

(52) U.S. Cl. 257/530; 438/466; 438/600; 438/601; 257/529; 257/E23.147; 257/E23.149; 257/E21.591; 257/E21.327

(57) ABSTRACT

A method for controlling the electrical conduction between two electrically conductive portions may include placing of an at least partially ionic crystal between the two electrically conductive portions. The crystal may include at least one surface region coupled to the two electrically conductive portions. The surface region is insulating under the application of an electrical field to the surface region, and electrically conductive in the absence of the electrical field. An application or not of an electrical field to the at least one surface region reduces or establishes the electrical conduction.

### FIELD OF THE INVENTION

The invention relates to the electrical switching between two electrically conductive portions, notably in an integrated circuit.

### SUMMARY OF THE INVENTION

According to one implementation and embodiment, a switching device or switch may be relatively simple and may have a reduced size. The switching device may establish an electrical link between two electrically conductive portions, for example, situated in the interconnect part, commonly referred to by those skilled in the art as “back-end-of-line” (BEOL).

According to one aspect, a method for controlling the electrical conduction between two electrically conductive portions may include placing of an at least partially ionic crystal between the two electrically conductive portions. The crystal may include at least one surface region coupled to the two electrically conductive portions. The surface region may be electrically insulating under the application of an electrical field to the surface region and electrically conductive in the absence of the electrical field. An application of an electrical field to the at least one surface region may reduce or establish the electrical conduction.

Preferably, the crystal comprises a first and a second opposing surface region. The application of the electrical field comprises an application of a potential difference between two electrically conductive regions respectively positioned at a distance from and facing the two surface regions.

The crystal preferably has a forbidden band (E_{Gap}) of at least 2 eV, and preferentially at least 3 eV, so as to exhibit good insulating characteristics when an electrical field is applied to the surface regions. The crystal may be a metallic oxide or an alkaline halide.

According to another aspect, in one embodiment, a device may include an at least partially ionic crystal that may include at least one surface region to be coupled between two electrically conductive portions. The surface region may be electrically insulating under the application of an electrical field to the surface region and conductive in the absence of the electrical field. A control means or generator circuit may be suitable for generating an electrical field on the at least one surface region to reduce or establish an electrical conduction between the electrically conductive portions.

Preferably, the crystal comprises a first surface region and a second surface region that are symmetrically opposite. The control means or generator circuit may comprise a first electrically conductive region and a second electrically conductive region, respectively, at a distance from and facing the first surface region and the second surface region. The control means may include means or a voltage generator configured to apply a potential difference between the first electrically conductive region and the second conductive region. The device preferentially comprises a first insulating area separating the first electrically conductive region from the first surface region and a second insulating area separating the second electrically conductive region from the second surface region.

According to another aspect, an integrated circuit may incorporate the switching device. Advantageously, the integrated circuit includes at least three metallization levels. A first metallization level may include the two electrically conductive portions, and at least a part of the crystal of the device may include at least one surface region positioned between the two electrically conductive portions. The two other levels may be placed on either side of the first metallization level and may include the two electrically conductive regions of the device.

### BRIEF DESCRIPTION OF THE DRAWINGS

FIG. 1 schematically shows the crystalline structure of zinc oxide in accordance with the prior art.

FIG. 2 schematically shows a band structure of an at least partially ionic crystal comprising at least one surface region that is conductive in the absence of an electrical field in accordance with the prior art.

FIG. 3 schematically illustrates one embodiment of a device according to the present invention.

FIGS. 4a-4e show exemplary steps of a first embodiment of a device according to the present invention.

FIGS. 5a-5e show exemplary steps of a second implementation of a method for producing a device according to the present invention.

### DETAILED DESCRIPTION OF THE PREFERRED EMBODIMENTS

Other benefits and features of the invention will become apparent from studying the detailed description of embodiments that are in no way limiting, and the appended drawings. An ionic crystal is a crystal in which the bonds between atoms are of an essentially ionic nature, that is to say, a crystal mainly comprising ions bonded together by their electrostatic attraction. The alkaline halides, such as sodium chloride, are ionic crystals. Most of the metallic oxides have a predominant ionic nature, and are therefore partially ionic crystals. In silicon oxide, the bond between the silicon and the oxygen is not entirely ionic, but includes a significant covalent contribution. The ionic nature of the bond stems from the fact that the wave function or the molecular orbital is mostly centered on one of the atoms of the bond. In the case of a metal-oxygen bond, the metallic atom tends to give away an electron, whereas the oxygen tends to gain it. In the case where the bond is mainly ionic, the charge of the oxygen is negative and that of the metal positive. In a crystalline structure, there is therefore planes which have a polar nature, if, for example, they include a majority of atoms having the same ionic valence.

For example, in a face-centered cubic (FCC) structure, such as sodium chloride (NaCl), the planes perpendicular to the crystalline direction [1,0,0] include as many positive ions as negative ions, and do not exhibit any polar nature. However, the planes perpendicular to the crystalline direction [1,1,0] include only positive ions or only negative ions. These planes therefore have a polar nature.

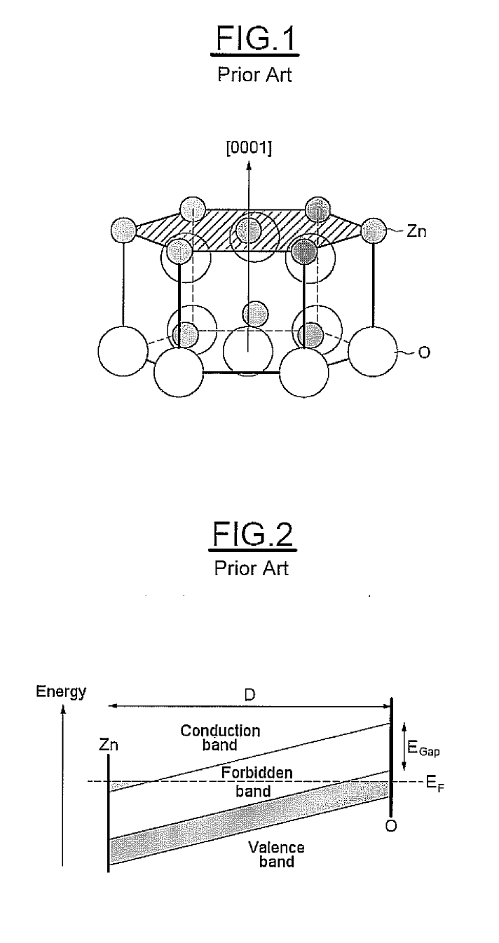

This feature is shared by the metallic oxides when an ionic or partially ionic crystal, such as a zinc oxide (ZnO) represented in FIG. 1, is produced or else cleaved to include at least one surface having a majority of atoms of a first species (Zn in the case in point), and at least one other surface having a majority of atoms of a second species (O in the case in point), such as, for example, on two distinct planes perpendicular to the crystalline direction [0,0,0,1]. If such a crystal has two faces corresponding to polar planes of opposite charges, then there is a potential drop between the two faces.

It has been observed, notably in the article entitled “Polarity in oxide ultrathin films” by C. Noguera and J. Goniakowski published in J. Phys.: Condens. Matter 20 (2008) 264003, that, when this potential drop is sufficient, the Fermi level may be situated above the conduction band as is illustrated in FIG. 2. In this figure, D designates the distance between the two polar surfaces (surface regions) respectively having, for example, a majority of zinc atoms (Zn) and a majority of oxygen atoms (O).

When the insulating ionic or partially ionic crystal does not exhibit any particular cleavage, the valence and conduction bands each possess an energy level that is constant through the crystal because there is no potential drop in the insulator, and the Fermi level E_{F} is situated between the two bands, that is to say in the forbidden band. When the crystal has polar surfaces, on the other hand, the energy bands vary linearly with the distance, because the energy variation is proportional to the potential drop which in turn varies linearly with the distance to the electrode. This linear variation and the penetration of the Fermi level into the bands is illustrated in FIG. 2. By definition, when the Fermi level E_{F} is in the conduction band, the material becomes conductive. In the present case, according to FIG. 2, it is the surface which then becomes conductive.

By application of an external electrical field opposite to the field caused by the surface charges, it is possible to compensate for the field in the dielectric. Because of this, the Fermi level E_{F} reverts to being between the energy bands, and the surfaces become insulating. In this way, it is possible to control the surface conduction by a field effect.

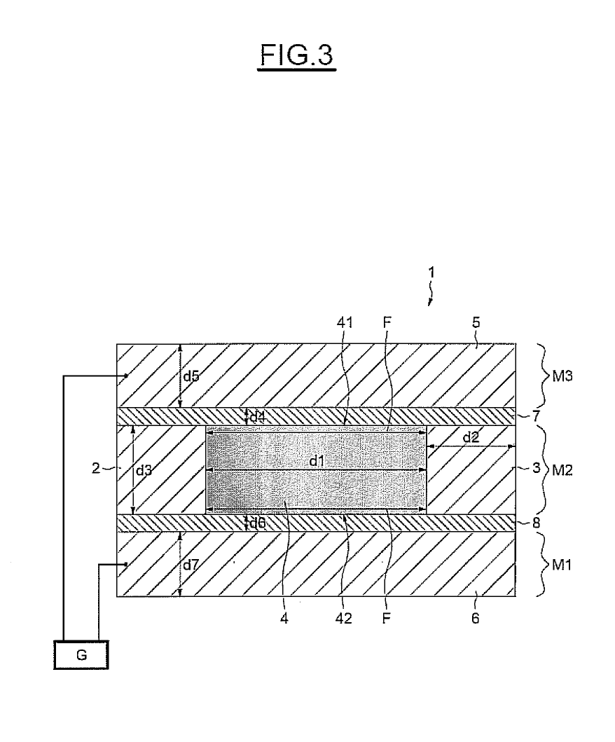

The device according to an embodiment uses this property. FIG. 3 shows a device 1 that controls the electrical conduction between a first electrically conductive portion 2, for example metallic, and a second electrically conductive portion 3, for example metallic. The device 1 is therefore like a switch making it possible to establish, or not, an electrical link between these two electrically conductive portions.

The device 1 comprises an at least partially ionic crystal 4 placed between the two metallic portions 2 and 3 so as to be able to electrically couple them to one another. The crystal 4 may be produced with an alkaline halide, such as, for example, sodium chloride (NaCl), or with a metallic oxide, such as, for example, zinc oxide (ZnO), manganese oxide (MnO), magnesium oxide (MgO), or even nickel oxide (NiO), zirconia or zirconium oxide (ZrO₂).

In this exemplary embodiment, the crystal 4 comprises a first surface region 41 and a second surface region 42 extending between the two metallic portions 2 and 3. The two surface regions 41 and 42 are produced to be insulating under the application of an electrical field on the surface regions, and electrically conductive in the absence of the electrical field.

The device 1 also comprises a first control metallic region 5 and a second control metallic region 6. The two control metallic regions 5 and 6 are positioned on either side of the assembly comprising the crystal and the two metallic portions 2 and 3. Thus, the first control metallic region 5 is positioned facing the first surface region 41 of the crystal 4, whereas the second control metallic region 6 is positioned facing the second surface region 42 of the crystal 4. The control metallic regions 5 and 6 are respectively separated from the crystal on the one hand, and from the metallic portions 2 and 3 on the other hand, by a first dielectric area 7 and a second dielectric area 8. The dielectric areas 7 and 8 may be replaced by other insulators or a void.

This being the case, the control metallic electrodes 5 and 6 may be limited in size to be situated facing the crystal 4 only. The first and second control metallic regions 5 and 6 make it possible to generate an electrical field reducing the conduction of the first and second surface regions 41 and 42. The electrical field is generated by the application of a potential difference between the first metallic region 5 and the second metallic region 6. The potential difference can, for example, be applied using a voltage generator G coupled to the first control metallic region 5, on the one hand, and the second control metallic region 6, on the other hand.

Moreover, the crystal 4 is produced in such a way that, in the absence of electrical field, the first surface region 41 has a charge opposite to that of the second surface region 42. In other words, the first surface region 41 exhibits a majority of atoms of the first species (for example Zn) and the second surface region 42 exhibits a majority of atoms of the second species (for example O). As an indication, a surface region exhibiting a majority of atoms of a given species is a surface exhibiting at least 50% of atoms of the given species. In this way, by applying a potential difference between the two control metallic regions 5 and 6, an electrical field is generated on each of the two surface regions 41 and 42.

Also, the thickness d4 and d6 of the dielectric areas 7 and 8 separating the control metallic regions 5 and 6 from the crystal 4 is relatively small so as to use small potentials on the control metallic regions 5 and 6. Indeed, the greater the thickness d4 or d6 of a dielectric area 7 or 8, the higher the potential imposed on a control metallic region 5 or 6 has to be to generate an electrical field that makes it possible to have an insulating surface region 41 or 42.

Conventionally, an integrated circuit comprises a part commonly referred to by those skilled in the art as “front-end-of-line” (FEOL), topped by a second part, commonly referred to by those skilled in the art as “back-end-of-line” (BEOL). The FEOL part is in fact the first part of the integrated circuit to be fabricated, wherein the usual active components, such as, for example, transistors, resistors, etc. are typically located. The FEOL part generally encompasses all the various elements of the integrated circuit as far as the first metallization layer.

The top part of the integrated circuit, namely the BEOL part, is the part of the integrated circuit in which the active components are interconnected via an interconnect network comprising metallization levels forming interconnect tracks or lines, and vias. This BEOL part generally begins with the first metallization level and it also includes the vias, the insulating layers, and the bump contact positioned on the top part of the integrated circuit.

Such a device 1 can be produced in the BEOL part of an integrated circuit to control the electrical conduction between, for example, two metallic portions situated in this BEOL part. In this case, the device 1 can be produced, for example, with a crystal 4 of zinc oxide (ZnO) having a length d1=45 nm, the first and the second metallic portions 2 and 3 made of copper (Cu) having a length d2=45 nm. The crystal 4 and the two electrical portions 2 and 3 have a thickness d3=5 nm. The first and second dielectric areas 7 and 8 made of silicon dioxide (SiO₂) have a thickness d4=d6=3 nm, and the first and second control metallic regions 5 and 6 made of copper (Cu) have a thickness d5=d7=20 nm.

The two control metallic regions 5 and 6 can be produced within two different metallization levels M1, M3 of the BEOL part, whereas the crystal 4 and the metallic portions 2 and 3 can be produced within another metallization level M2. The inter-metal dielectrics can be used to form the dielectrics 7 and 8 of the device.

In the absence of any potential difference applied to the two control metallic regions 5 and 6 by the voltage generator G, the surface regions 41 and 42 are electrically conductive and allow for an electrical coupling between the two metallic portions 2 and 3 via the surface regions 41 and 42 (arrows F).

On the other hand, when a potential difference is applied between the two control metallic regions 5 and 6, an electrical field appears respectively between the first control metallic region 5 and the first surface region 41, and the second control metallic region 6 and the second surface region 42. The electrical field then modifies the molecular wave functions of the surface regions 41 and 42, reducing any electrical conduction of the surface regions 41 and 42. The metallic portions 2 and 3 are then mutually electrically insulated by the crystal 4.

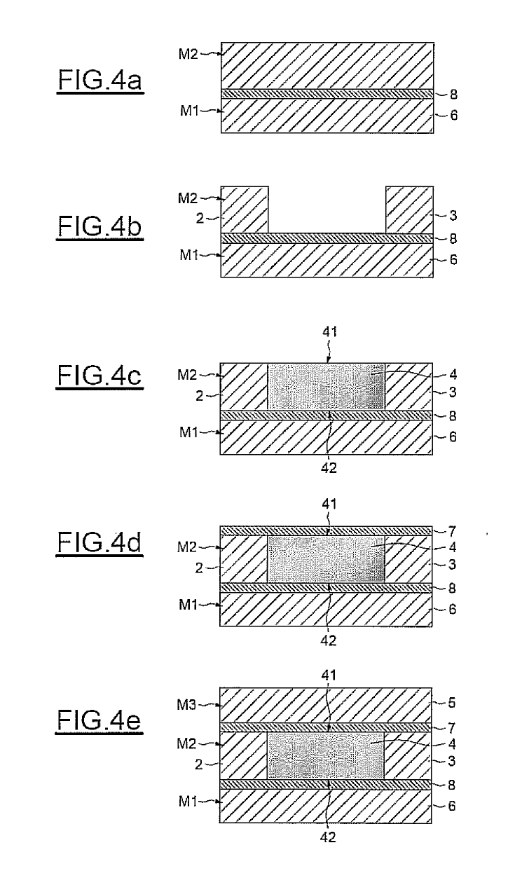

FIGS. 4a-4e show the steps of a first implementation of a method for producing a device 1 within the BEOL part of an integrated circuit. In a first step illustrated in FIG. 4a, a second metallization level M1 (for example, made of copper) and a first metallization level M2 (for example, made of copper) are produced within a semiconductor substrate and separated by a dielectric area. The second metallization level M1 comprises the second control metallic region 6, and the inter-metal dielectric area comprises the second dielectric area 8.

In a second step illustrated in FIG. 4b, the first metallization level M2 is etched. This etching makes it possible to define, in the first metallization level M2, the first metallic portion 2 and the second metallic layer 3.

In a third step illustrated in FIG. 4c, an at least partially ionic crystal 4, such as, for example, a crystal of zinc oxide (ZnO), is grown by epitaxy with IBS (ion beam sputtering) in the cavity separating the first metallic portion 2 and the second metallic portion 3. The epitaxy is done in such a way that the crystal 4 comprises a first surface region 41 comprising a majority of atoms of a first species and a second surface region 42 comprising a majority of atoms of a second species. In this respect, it may be possible to use, for the epitaxy, an ion beam sputtering (IBS) oriented [1,0,0,0] on a first surface and [0,0,0, 1̅] on a second surface. Such an epitaxy technique is known to those skilled in the art. Those skilled in the art can refer, in particular, to the article entitled “Dual-ion-beam sputter deposition of ZnO films” by F. Quaranta et al., published in the journal J. Appl. Phys. 74 (1), 1 Jul. 1993. On completion of the epitaxy, the crystal 4 can be subjected to a mechano-chemical polishing.

In a fourth step illustrated in FIG. 4d, another dielectric area is produced, covering the two metallic portions 2 and 3 and the crystal 4. The dielectric area comprises the first dielectric area 7. It is produced by deposition of a layer of silicon dioxide (SiO₂), for example, and by mechanical-chemical polishing.

Finally, in a fifth step illustrated in FIG. 4e, the third metallization level M3, for example, of copper (Cu), is produced. The third metallization level M3 comprises the first control metallic region. It can also be smoothed by mechanical-chemical polishing.

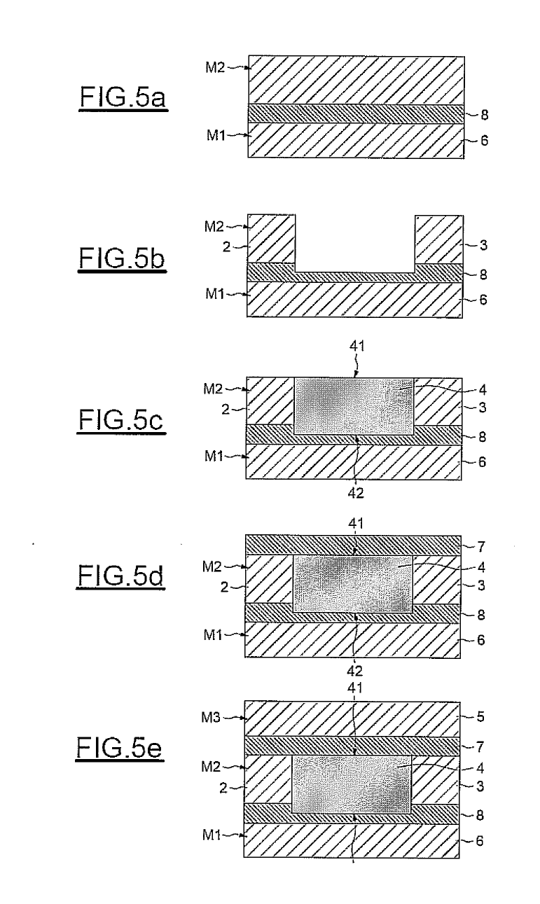

FIGS. 5a-5e show the steps of a second implementation of a method for producing a device within the BEOL part. In a first step illustrated in FIG. 5a, as in step 4a, a second metallization level M1 (for example, of copper) and a first metallization level M2 (for example, of copper) are produced within a semiconductor substrate and separated by a dielectric area. The second metallization level M1 comprises the second control metallic region 6, and the inter-metal dielectric area comprises the second dielectric area 8.

In a second step illustrated in FIG. 5b, the first metallization level M2 and the dielectric area are etched. This etching makes it possible to define, in the first metallization level M2, the first metallic portion 2 and the second metallic layer 3. This etching differs, however, from the etching of the first embodiment illustrated in FIG. 4b in that it is carried out over the entire thickness of the first metallization level M2 as well as on a part of the thickness of the dielectric area 8 separating the second metallization level M1 from the first metallization level M2.

In a third step illustrated in FIG. 5c, an at least partially ionic crystal 4, such as, for example, a crystal of zinc oxide (ZnO), is grown by epitaxy with IBS (ion beam sputtering) in the cavity separating the first metallic portion 2 and the second metallic portion 3. The epitaxy is carried out in a way similar to that described with reference to FIG. 4c, so that the crystal 4 comprises a first surface region 41 comprising a majority of atoms of a first species and a second surface region 42 comprising a majority of atoms of a second species. On completion of the epitaxy, the crystal 4 can be subjected to a mechanical-chemical polishing.

The fourth step illustrated in FIG. 5d and the fifth step illustrated in FIG. 5e are similar to the corresponding steps illustrated in FIGS. 4d and 4e.

In this embodiment, the device 1 comprises a crystal 4, which conducts between the metallic portions 2 and 3 only via the first surface region 41 coupled between the metallic portions 2 and 3. Indeed, even if the crystal 4 is produced to obtain a second surface region 42 capable of being electrically conductive in the absence of any electrical field, the second surface region 42 is not electrically in contact with the metallic portions 2 and 3. Indeed, the second surface region is situated in the second dielectric area 8, and is, consequently, electrically insulated from the metallic portions 2 and 3.

The device 1 could also be produced in the FEOL part of the integrated circuit. It could also be produced to form a specific component without necessarily being integrated in the BEOL or the FEOL of an integrated circuit.

1-14. (canceled)

15. A method for controlling electrical conduction between two electrically conductive portions, the method comprising:
positioning an at least partially ionic crystal between the two electrically conductive portions, the at least partially ionic crystal comprising at least one surface region coupled to the two electrically conductive portions, the surface region being electrically insulating when an electrical field is applied to the at least one surface region and electrically conductive in an absence of the electrical field; and
selectively applying an electrical field to the at least one surface region to control the electrical conductivity thereof.

16. The method according to claim 15, wherein the at least one surface region comprises first and second opposing surface regions, and wherein selectively applying the electrical field comprises selectively applying a voltage between two electrically conductive regions respectively positioned at a distance from the first and second opposing surface regions.

17. The method according to claim 15, wherein the at least partially ionic crystal has a forbidden band of at least 2 eV.

18. The method according to claim 15, wherein the at least partially ionic crystal has a forbidden band of at least 3 eV.

19. The Method according to claim 15, wherein the at least partially ionic crystal comprises a metallic oxide.

20. The method according to claim 15, wherein the at least partially ionic crystal comprises an alkaline halide.

21. A method of making an integrated circuit (IC) comprising:
providing a semiconductor substrate; and
forming a switching device on the substrate by at least
forming two electrically conductive portions,
coupling at least one surface region of an at least partially ionic crystal between the two electrically conductive portions, the at least one surface region configured to be electrically insulating when an electrical field is applied thereto and configured to be electrically conductive in an absence of the electrical field, and
coupling control circuitry so that a generated electrical field on the at least one surface region controls electrical conduction between the electrically conductive portions.

22. The method according to claim 21, wherein coupling the at least one surface region comprises coupling a first surface region and a second surface region symmetrically opposing the first surface region; wherein coupling the control circuitry comprises coupling a first electrically conductive region and a second electrically conductive region, respectively, to be spaced apart and facing the first surface region and the second surface region, and coupling a voltage generator to apply a voltage between the first electrically conductive region and the second electrically conductive region.

23. The method according to claim 22, wherein forming the switching device further comprises:
forming a first insulating area to separate the first electrically conductive region from the first surface region; and
forming a second insulating area to separate the second electrically conductive region from the second surface region.

24. The method according to claim 21, wherein the at least partially ionic crystal has a forbidden band of at least 2 eV.

25. The method according to claim 21, wherein the at least partially ionic crystal has a forbidden band of at least 3 eV.

26. The method according to claim 21, wherein the at least partially ionic crystal comprises at least one of metallic oxide and an alkaline halide.

27. The method according to claim 21, further comprising forming an interconnect layer above the semiconductor substrate; and wherein forming the switching device comprises forming the switching device in the interconnect layer.

28. The method according to claim 27, wherein forming the interconnect layer comprises forming at least three metallization levels, a first metallization level of the three metallization levels having the two electrically conductive portions therein and at least a portion of the at least partially ionic crystal; and wherein a second and third metallization level of the three metallization levels is positioned on opposing sides of the first metallization level and has the first and second electrically conductive regions therein.

29. A device comprising:
two electrically conductive portions;
an at least partially ionic crystal comprising at least one surface region configured coupled between said two electrically conductive portions, the at least one surface region configured to be electrically insulating when an electrical field is applied thereto and configured to be electrically conductive in an absence of the electrical field; and
control circuitry configured to generate an electrical field on the at least one surface region to control electrical conduction between said two electrically conductive portions.

30. The device according to claim 29, wherein the at least one surface region comprises a first surface region and a second surface region symmetrically opposing the first surface region; wherein said control circuitry comprises a first electrically conductive region and a second electrically conductive region, respectively, spaced apart and facing the first surface region and the second surface region, and a voltage generator configured to apply a voltage between the first electrically conductive region and the second electrically conductive region.

31. The device according to claim 30, further comprising:
a first insulating area separating the first electrically conductive region from the first surface region; and
a second insulating area separating the second electrically conductive region from the second surface region.

32. The device according to claim 29, wherein said at least partially ionic crystal has a forbidden band of at least 2 eV.

33. The device according to claim 29, wherein said at least partially ionic crystal has a forbidden band of at least 3 eV.

34. The device according to claim 29, wherein said at least partially ionic crystal comprises metallic oxide.

35. The device according to claim 29, wherein said at least partially ionic crystal comprises an alkaline halide.

36. An integrated circuit (IC) comprising:
a semiconductor substrate; and
a switching device carried by said substrate and comprising
two electrically conductive portions,
an at least partially ionic crystal comprising at least one surface region configured coupled between said two electrically conductive portions, the at least one surface region configured to be electrically insulating when an electrical field is applied thereto and configured to be electrically conductive in an absence of the electrical field, and
control circuitry configured to generate an electrical field on the at least one surface region to control electrical conduction between said electrically conductive portions.

37. The IC according to claim 36, wherein the at least one surface region comprises a first surface region and a second surface region symmetrically opposing the first surface region; wherein said control circuitry comprises a first electrically conductive region and a second electrically conductive region, respectively, spaced apart and facing the first surface region and the second surface region, and a voltage generator configured to apply a voltage between the first electrically conductive region and the second electrically conductive region.

38. The IC according to claim 37, wherein said switching device further comprises:
a first insulating area separating the first electrically conductive region from the first surface region; and
a second insulating area separating the second electrically conductive region from the second surface region.

39. The IC according to claim 36, wherein said at least partially ionic crystal has a forbidden band of at least 2 eV.

40. The IC according to claim 36, wherein said at least partially ionic crystal has a forbidden band of at least 3 eV.

41. The IC according to claim 36, wherein said at least partially ionic crystal comprises at least one of metallic oxide and an alkaline halide.

42. The IC according to claim 37, further comprising an interconnect layer above said semiconductor substrate; and wherein said switching device is positioned in the interconnect layer.

43. The IC according to claim 42, wherein the interconnect layer comprises at least three metallization levels, a first metallization level of said three metallization levels having said two electrically conductive portions and at least a portion of the at least partially ionic crystal therein; and wherein a second and third metallization level of said three metallization levels is positioned on opposing sides of said first metallization level and has said first and second electrically conductive regions therein.
